(19) United States
(12) Patent Application Publication
(10) Pub. No.: US 2025/0211314 A1
(43) Pub. Date: Jun. 26, 2025

(54) SYSTEMS, DEVICES AND METHODS FOR WIRELESS COMMUNICATION

(71) Applicant: Intel Corporation, Santa Clara, CA (US)

(72) Inventors: Maryam ESLAMI RASEKH, San Jose, CA (US); Hechen WANG, Portland, OR (US); Niranjan MYLARAPPA GOWDA, Hillsboro, OR (US); Andrey BELOGOLOVY, Hillsboro, OR (US)

(21) Appl. No.: 18/391,701

(22) Filed: Dec. 21, 2023

(51) Int. Cl. H04B 7/08; H03K 17/687

(52) U.S. Cl. CPC H04B 7/08; H03K 17/6872

(57) ABSTRACT

A radio communication system includes an antenna array comprising a plurality of antenna elements configured to receive a plurality of radio frequency (RF) signals, RF circuitry coupled to the antenna array configured to downconvert the RF signals to generate analog baseband signals, and analog processing circuitry coupled to the RF circuitry. The analog processing circuitry is configured to generate spatially compressed beamspace domain analog signals from the analog baseband signals.

### TECHNICAL FIELD

Various aspects of this disclosure generally relate to systems, devices, and methods for wireless communications.

### BACKGROUND

The high dimensionality of massive Multiple-input, Multiple-output (MIMO) frontends causes high computational complexity in the receiver as well as high bandwidth requirement between a radio unit (RU) and a data unit (DU). Spatial compression can be employed to reduce this dimensionality while conserving the information of all MIMO layers. Finding and applying the correct compression matrix can itself be computationally intensive and contribute to the power consumption of massive MIMO links. For example, a discrete Fourier transform (DFT) can be employed as a universal compression tool to transform signals from antenna domain to beam domain (or “beam-space”) where wireless channels are inherently sparse.

Alternatively, the conversion can be carried out in analog domain where it is typically more power efficient and low latency. One existing method for analog transformation to beam-space is via a physical lens or parabola 105 which, are shown in the radio communication system 100 of FIG. 1A and FIG. 1B. In both FIGS. 1A and 1B, the lens 105 focuses an incoming wave (e.g., plane wave) 10 from each direction on the corresponding (wavefront lens) antenna element 110a of an antenna array 110. Unfortunately, lenses are bulky and not suitable for deployment in most modern devices.

Another option is to use a butler matrix 200 in analog RF before down-conversion as shown in the radio communication system 200 of FIG. 2A. FIG. 2B shows the butler matrix 200 in more detail. This approach can be power efficient and suitable for integration but does not scale well with number of antennas as the maximum practical dimension is approximately 8.

FIG. 3 shows a radio communication system 300 in which beam-space compression is implemented digitally, using a digital signal processor (DSP) 310 that takes a Fast Fourier Transform (FFT) over the spatial dimension. The DSP 310 can be implemented after downconverters 130 are used and also requires a number of analog-to-digital converters (ADCs) 140.

The Fourier transform, for example a spatial DFT, transforms received signals to the spatial frequency domain or “beam-space”. As such, each angle of arrival is mapped to one output dimension, hence sparsifying the received signal vector and providing a natural, universal basis for fast and easy dimensionality reduction. One such example is shown in FIG. 4 for a 64-element antenna array 410 with 3 incoming signal paths 420a, 420b, 420c (rank 3 channel). FIG. 4 shows the signal received power in the graph 450 and the graph 460 shows the power of corresponding output after a FFT has been applied to digitized version of the signal.

Accordingly, as previously described, the spatial transformation to beam-space is either done in DSP using a spatial Fourier transform (FFT), or in analog RF using a lens or Butler matrix. Analog implementations typically involve passive components and are therefore inherently low power, with the added benefit of allowing simplification or power savings in downstream elements, e.g., activating fewer RF chains or ADCs. Despite these advantages, however, both conventional techniques for analog beam-space transformation have significant shortcomings: physical lenses are bulky and not suitable for implementation in many modern devices, and the Butler matrix architecture is not scalable to more than 8 elements due to the complexity of the circuitry and loss incurred by long RF transmission lines.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIGS. 1A and 1B each show a diagram of an aspect of a radio communication system.

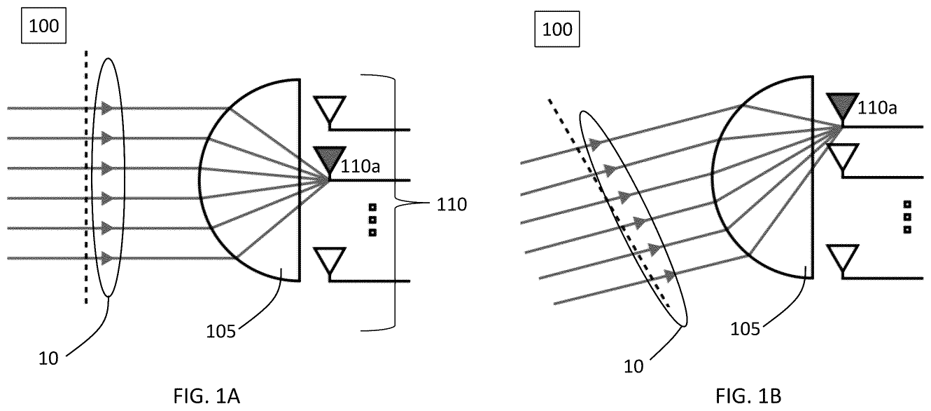

FIG. 2A shows a diagram of a radio communication system.

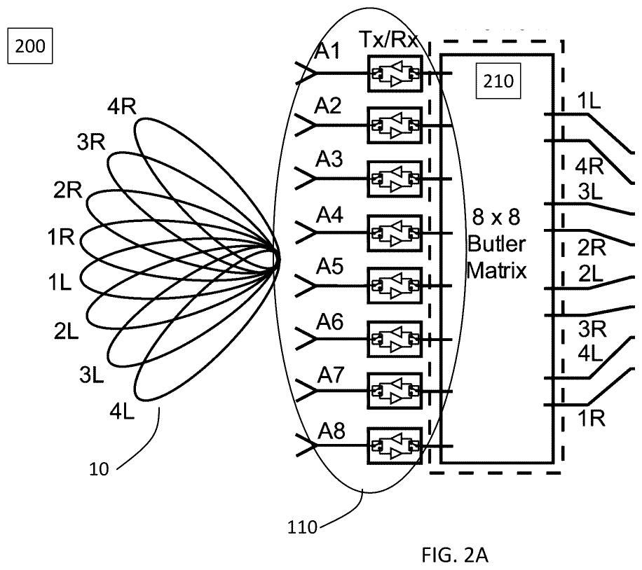

FIG. 2B shows an example of a butler matrix.

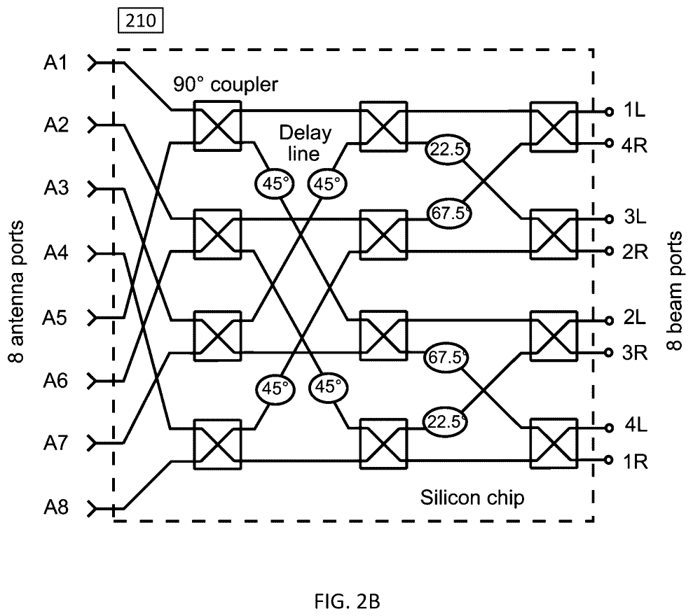

FIG. 3 shows a radio communication system/device.

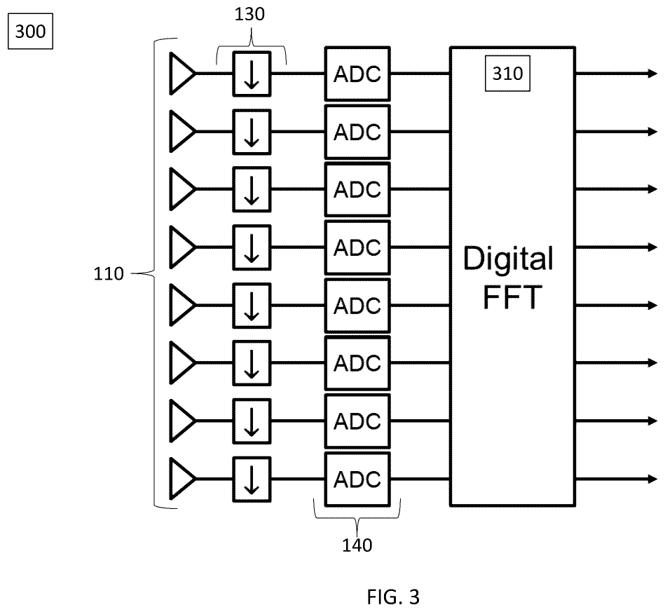

FIG. 4 shows graphical representation of signal received power before and after a FFT has been applied to a signal.

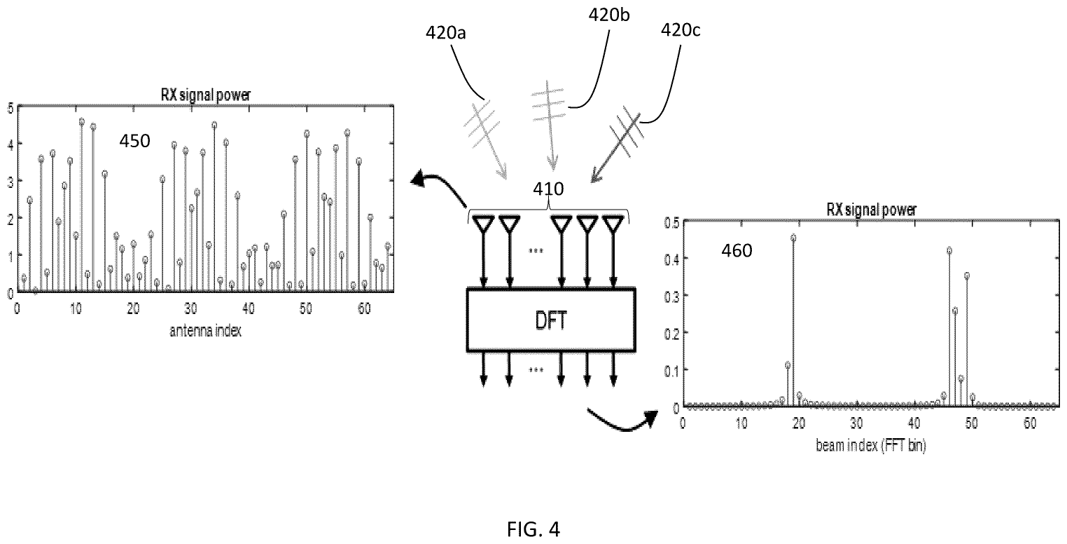

FIG. 5 shows a diagram of a radio communication device or system in accordance with aspects of the present disclosure.

FIG. 6 shows a diagram of a C-2C structure or network in accordance with aspects of the present disclosure.

FIG. 7 shows an example of a memory circuit and a MAC unit in accordance with aspects of the present disclosure.

FIG. 8 shows an example of an analog processing circuitry in accordance with aspects of the present disclosure.

### DESCRIPTION

The following detailed description refers to the accompanying drawings that show, by way of illustration, exemplary details and aspects in which the invention may be practiced.

The word “exemplary” is used herein to mean “serving as an example, instance, or illustration”. Any aspect or design described herein as “exemplary” is not necessarily to be construed as preferred or advantageous over other aspects or designs.

Reference to “one embodiment” or “an embodiment” in the present disclosure means that a particular feature, structure, or characteristic described in connection with the embodiment is included in at least one embodiment. The appearances of the phrase “in one embodiment” or “in an embodiment” are not necessarily all referring to the same embodiment. The appearances of the phrase “for example,” “in an example,” or “in some examples” are not necessarily all referring to the same example.

Throughout the drawings, it should be noted that like reference numbers are used to depict the same or similar elements, features, and structures unless otherwise noted.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.).

The words “plural” and “multiple” in the description and the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. The phrases “group (of)”, “set (of)”, “collection (of)”, “series (of)”, “sequence (of)”, “grouping (of)”, etc., and the like in the description and the claims, if any, refer to a quantity equal to or greater than one, i.e., one or more. The phrases “proper subset”, “reduced subset”, and “lesser subset” refer to a subset of a set that is not equal to the set, illustratively, referring to a subset of a set that contains fewer elements than the set.

The phrase “at least one of” with regard to a group of elements may be used herein to mean at least one element from the group, including the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in the form of a pointer. However, the term “data” is not limited to the examples mentioned above and may take various forms and represent any information as understood in the art.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit, and may also be referred to as a “processing circuit,” “processing circuitry,” among others. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality, among others, and conversely that any single processor, controller, or logic circuit described herein may be realized as two (or more) separate entities with equivalent functionality, among others.

As utilized herein, terms “module”, “component,” “system,” “circuit,” “element,” “slice,” “circuitry,” and the like are intended to refer to a set of one or more electronic components, a computer-related entity, hardware, software (e.g., in execution), and/or firmware. For example, circuitry or a similar term can be a processor, a process running on a processor, a controller, an object, an executable program, a storage device, and/or a computer with a processing device. By way of illustration, an application running on a server and the server can also be circuitry. One or more circuits can reside within the same circuitry, and circuitry can be localized on one computer and/or distributed between two or more computers. A set of elements or a set of other circuits can be described herein, in which the term “set” can be interpreted as “one or more.”

As used herein, “memory” is understood as a computer-readable medium in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, among others, or any combination thereof. Registers, shift registers, processor registers, data buffers, among others, are also embraced herein by the term memory. The term “software” refers to any type of executable instruction, including firmware.

Unless explicitly specified, the term “transmit” encompasses both direct (point-to-point) and indirect transmission (via one or more intermediary points). Similarly, the term “receive” encompasses both direct and indirect reception. Furthermore, the terms “transmit,” “receive,” “send,” “communicate,” and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as RF transceivers and antennas, and the processors or controllers perform the logical transmission and reception over the software-level connection. The term “communicate” encompasses one or both of transmitting and receiving, i.e., unidirectional or bidirectional communication in one or both of the incoming and outgoing directions. The term “calculate” encompasses both ‘direct’ calculations via a mathematical expression/formula/relationship and ‘indirect’ calculations via lookup or hash tables and other array indexing or searching operations.

As used herein, a signal that is “indicative of” a value or other information may be a digital or analog signal that encodes or otherwise communicates the value or other information in a manner that can be decoded by and/or cause a responsive action in a component receiving the signal. The signal may be stored or buffered in a computer-readable storage medium prior to its receipt by the receiving component. The receiving component may retrieve the signal from the storage medium. Further, a “value” that is “indicative of” some quantity, state, or parameter may be physically embodied as a digital signal, an analog signal, or stored bits that encode or otherwise communicate the value.

As used herein, a signal may be transmitted or conducted through a signal chain in which the signal is processed to change characteristics such as phase, amplitude, frequency, and so on. The signal may be referred to as the same signal even as such characteristics are adapted. In general, so long as a signal continues to encode the same information, the signal may be considered as the same signal. For example, a transmit signal may be regarded as referring to the transmit signal in baseband, intermediate, and radio frequencies.

As used herein, unless otherwise specified the use of the ordinal adjectives “first”, “second”, “third” etc., to describe a common object, merely indicate that different instances of like objects are being referred to and are not intended to imply that the objects so described must be in a given sequence, either temporally, spatially, in ranking, or in any other manner.

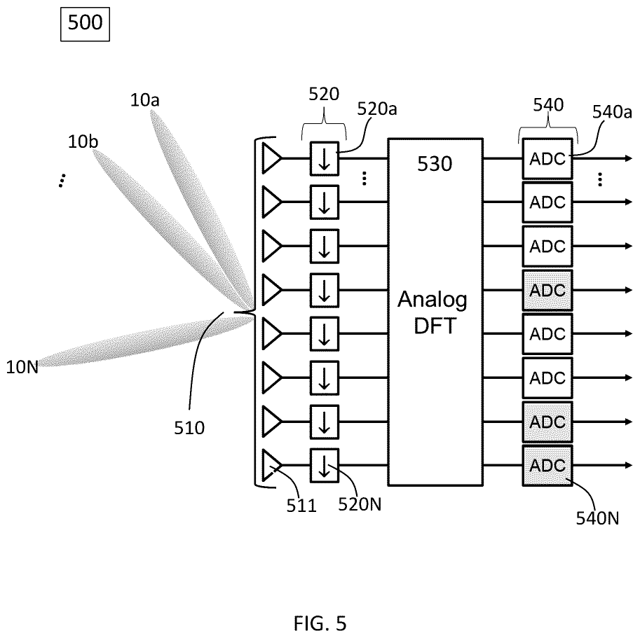

FIG. 5 shows a diagram of a radio communication system 500 according to at least one example of the present disclosure. The radio communication system 500 may be configured to operate MIMO according to, for example, 5G or 6G protocols, and may be operate according to a massive MIMO scheme.

The radio communication system includes an antenna array 510 including a plurality of antenna elements 511. The antenna array may include a two-dimensional (2D) or three-dimensional (3D) array of antenna element 511.

The antenna array 510 is configured to receive one or more signals 10a . . . 10N (10). For example, the signals 10 may be sent according to a MIMO protocol. The signals 10 received the antenna array 510 can be forwarded to RF circuitry, e.g., to a plurality of RF chains. The RF chains may be or include the plurality of RF downconverters 520 (520a . . . 520N). That is, each antenna element 511 can forward its received signal to a corresponding or respective RF chain/RF downconverter 520.

The RF chains/downconverters 520 are configured to downconvert the RF signal signals received from the antenna array 510. In at least one example, the RF downconverters 520 convert the RF signals to (analog) baseband. The RF downconverters may be any suitable type of RF downconverters may be used to produced downconverted analog baseband signals. For example, the RF downconverters may include any suitable combinations of local oscillators, mixers, filters in one or more stages.

The downconverted signals, e.g., analog baseband signals, can be input into analog processing circuitry 530. The analog processing circuitry 530 can be configured to produce or generate spatially transformed or spatially compressed analog baseband signals from received input, namely from the downconverted signals (e.g., baseband signals). Said differently, the analog compression circuitry produces spatially compressed or spatially transformed beamspace domain analog signals.

In at least one example, to generate the spatially compressed/transformed analog signals (spatially compressed beamspace domain analog signals), the analog processing circuitry 530 is configured to apply, in analog, a spatial Fourier transform to the analog baseband signals. Said differently, the analog processing circuitry 530 applies a spatial Fourier transform, in the analog domain, to obtained baseband signals. That is, the applied spatial Fourier transform may be considered as an analog equivalent of the discrete Fourier Transform.

As shown in the example of FIG. 5, the analog processing circuitry 530 can generate a spatially compressed analog signal (also referred to herein as spatially transformed analog signal or spatially compressed beamspace domain analog signal) for each analog baseband signal it receives. That is, for N baseband signals submitted as input, the analog processing circuitry 530 can produce, e.g., in parallel, N outputs or N spatially compressed signals. In other instances, there may not be a one-to-one correspondence between the output signals and the input signals to the analog processing circuitry 530. That is, there may be more or fewer output signals in comparison to the input signals to the analog processing circuitry 530.

The spatially compressed analog signals or spatially compressed beamspace domain analog signals generated by the analog processing circuitry 530 can then be forwarded to other components for further processing. For instance, the spatially compressed analog signals generated by the analog processing circuitry can be digitized.

In FIG. 5, each of the N generated spatially compressed analog signals can be sent to a plurality of analog-to-digital converter (ADCs) 540a-540N (540). More specifically, each generated spatially compressed analog signal can be sent to a respective ADCs 540 for digitizing. The digital signals produced by the ADCs 540 can then forwarded to processing circuitry, e.g., to a data unit (DU) of a radio, e.g., of the radio communication system 500.

As previously mentioned in the context of FIG. 5, the analog processing circuitry 530 can generate a spatially compressed or spatially transformed analog signal for each analog baseband signal it receives, and more specifically can implement, in the analog domain, the equivalent of the (2D) DFT. Since the DFT is a linear transform requiring simple multiplications and additions, it may be implemented using multiply-accumulate (MAC) circuit or MAC unit. More specifically, the spatial Fourier transform can be implemented in analog domain using a plurality of MAC circuits. For example, the plurality of MAC units/circuits may be implemented as a grid of MAC units/circuits.

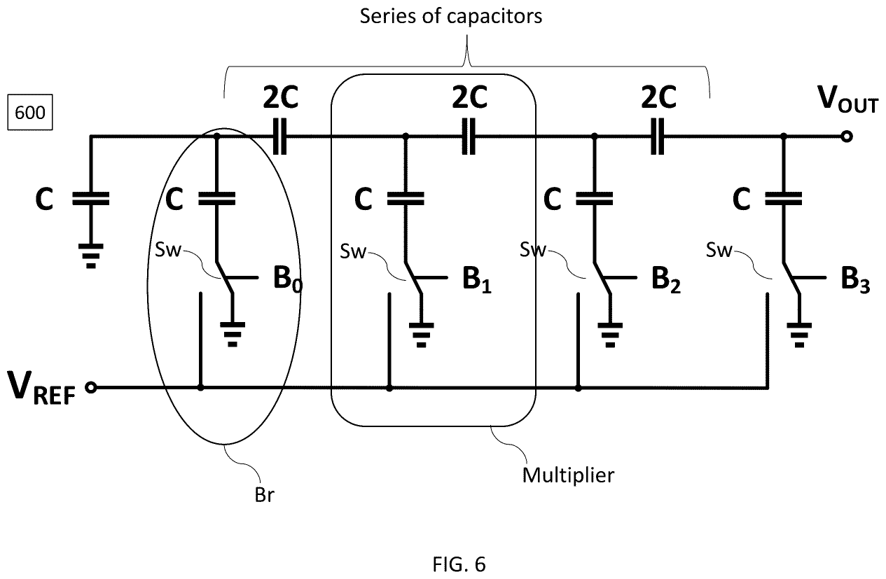

One way to implement an individual MAC circuit is through a capacitor network structure, such as a C-2C structure which is shown in FIG. 6. That is a MAC unit may include a C-2C structure for the multiplication part of the MAC unit. This type of network 600 can be used in digital-to-analog converters (DACs) and is designed to provide lower power analog voltage outputs.

As in FIG. 6, the C-2C structure or network 600 includes a series of second capacitors 2C segmented by branches Br. Each branch Br includes a first capacitor C in series with a switch Sw. The switches Sw can selectively couple its respective branch Br to a reference potential V_{REF} or a ground node (GND). That is, each branch Br may couple, e.g., at one end to nodes between a pair of consecutive second capacitors 2C in series, or between a second capacitor and a terminal send of the series of second capacitors 2C.

In other words, in the C-2C networks such as network 600, a plurality second capacitors 2C arranged in series (e.g., serially connected) and each of the second capacitors C2 is located between branches Br of the plurality of branches.

In FIG. 6, the switches Sw may be respectively controlled by digital bits Bᵢ (e.g., B₀-B₃). These digital bits Bᵢ can be derived or correspond to a binary representation of multiplication weights.

Further, for the network 600, the second capacitors 2C have twice the capacitance of first capacitor C.

In the example of FIG. 6, the output (V_{OUT}) of the network 600 can be expressed as:

$${V}_{O U T} = {V}_{R E F} {\sum }_{i = 0}^{m - 1} {B}_{i} \times \frac{1}{{2}^{m - i}}$$

where m is the number of branches, and
where V_{REF} represents the input (voltage) value for a multiplication block.

Or V_{OUT} can be expressed as:

$${V}_{O U T} = {V}_{R E F} {\sum }_{i = 0}^{m - 1} {W}_{i}$$

$$where {W}_{i} = {\sum }_{i = 0}^{m - 1} {B}_{i} \times \frac{1}{{2}^{m - i}}$$

As shown, the output, V_{OUT}, is the effectively the sum or accumulated output of the products of the weights with the input, V_{REF}. The C-2C ladder structure makes it very easy to scale up the number of bits by simply adding branches to the ladder. In the example of FIG. 6, shows C-2C ladder network 600 with a 4-bit resolution. A set of single branches (a branch including a capacitor C and Switch Sw) and a capacitor 2C can be considered a multiplier of the network 600.

As described, the switches of the networks, such as the network 600, are controlled by digital bits that are representative of multiplication weights used for implementing the spatial Fourier Transform by an analog processing circuitry. These digital bits may be provided to the MAC units from any suitable (e.g., non-volatile) memory or memory circuit/device.

In one instance, digital bits that are representative of the weights may be stored in Static Random-Access Memory (SRAM) cells. The SRAM cells 700 can provide the digital bits to the multiplier of the MAC unit 750.

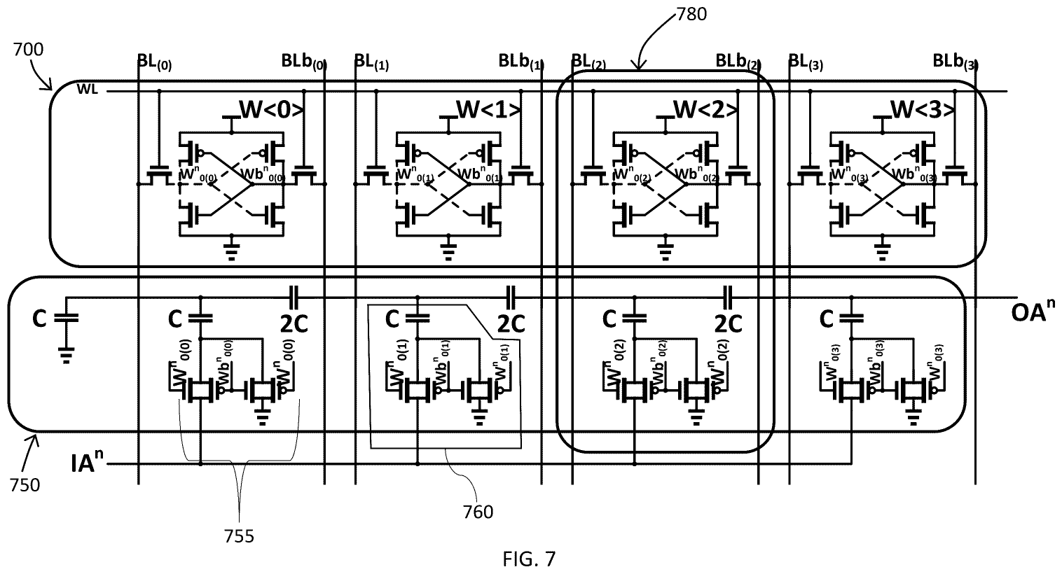

FIG. 7 shows an exemplary of one circuit arrangement 700 of an implementation of a memory circuit 710 and a MAC unit/circuit 750. The circuit arrangement 700 may be considered as part of the analog processing circuitries described herein.

As shown, the memory circuit 710 can be implemented as memory cells, e.g., SRAM cells. The MAC unit 750 is implemented in this instance as a 4-bit C-2C ladder circuit such as or similar to the one described in the example of FIG. 6. However, in other cases, more cells to the MAC unit/circuit 750 can be implemented and realized.

The example of FIG. 7 shows a 4 SRAM cells implemented in a six-transistor configuration. Each SRAM can hold a bit value Wⁿₓ₍ₓ₎ and its inverse value Wbⁿₓ₍ₓ₎, which can be provided, e.g., to the MAC unit 750 through the bit lines BL and BLb. In FIG. 7, each SRAM cell provides its stored digital bits to a corresponding MAC unit, e.g., to a corresponding multiplier or multiplier cell. For example, the closed line 770 shows a how one SRAM cell corresponds to one (multiplier) cell of the MAC unit 750, which together can be considered as one cell.

MAC units or MAC circuits described herein may be implemented such as what is depicted in FIG. 7. The MAC unit 750 may be implemented in Complementary Metal-Oxide-Semiconductor (CMOS) technology. Further, the MAC unit 750 includes a capacitor network structure (C-2C) such as which is shown in FIG. 6. The switches Sw of the capacitor network 600 correspond to the pair of gate circuits 755. As shown, the gate circuits 755 receive a digital input value, and the inverse.

The capacitors (the first capacitor C and second capacitors 2C) can be implemented as metal-oxide-metal capacitors. The closed line 760 shows a branch correspond to the branch Br of the C-2C network 600 of FIG. 6. The output of the circuit, OA, is the accumulation of the analog charges of the individual MAC unit 750.

The memory circuit 710 and the MAC unit 750 may be arranged and/or implemented together. For example, the memory circuit 710 and the MAC unit 750 may be integrated together, e.g., pairwise, so that each memory cell can easily provide digital bits or weights (stored digital values) to a corresponding MAC unit cell, e.g., multiplier. The encircled part 780 of the memory circuit 710 and the adjacent or immediate neighboring MAC multiplier can be considered as one pair or a single cell 780. Each cell may correspond to one bit. In the example of FIG. 7, the memory circuit 710 and the MAC unit can include 4 cells 780. Further, both the memory circuit 710 and the MAC unit 750 can be integrated together and may share, for example, a shared substrate with both implemented using CMOS.

To implement analog processing circuitry, such as the analog processing circuitry 530 in the example of FIG. 5, the MAC units and memory circuits described herein can be realized, for example, in a grid structure, in order to perform a spatial Fourier transform on inputted signals (e.g., downconverted signals from an antenna array).

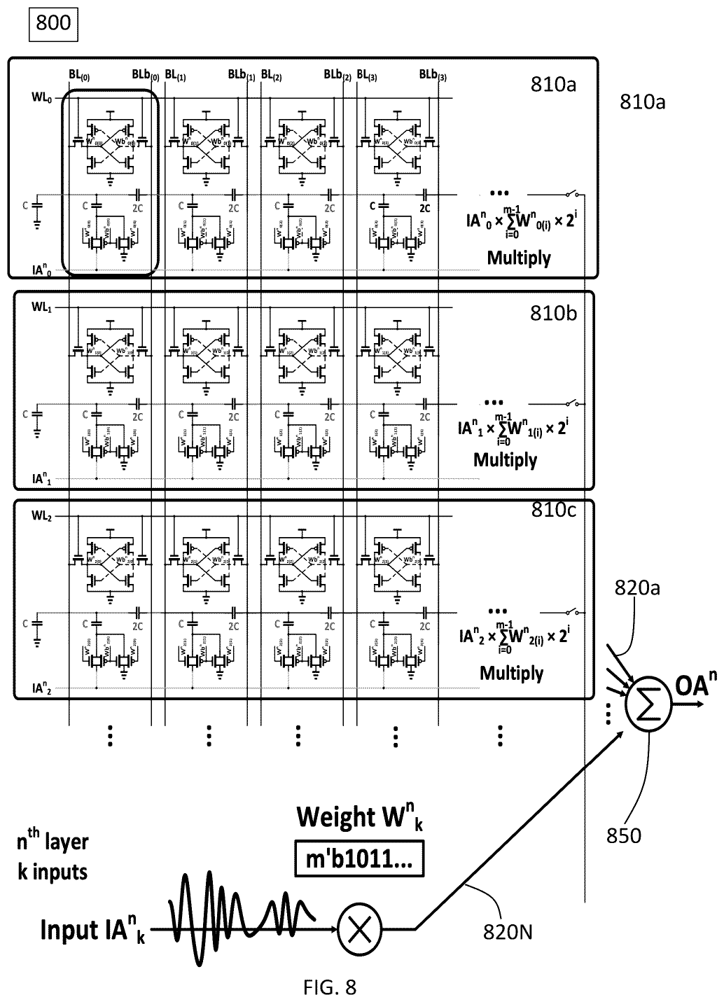

FIG. 8 shows an example 800 of at least aspect of an analog processing circuitry 800 described. The analog processing circuitry 800, as described herein, is configured to performing spatial compression, e.g. perform analog version of spatial Fourier transform (e.g. DFT).

The analog processing circuitry 800 of FIG. 8 includes a plurality of MAC units 810. More specifically, the MAC units 810 may be implemented in a grid-like or similar structure. In FIG. 8, the analog processing circuitry 800 incudes MAC units/circuits 810a, 810b, 810c . . . and 810N which form a single layer. The analog processing circuitry 800 can include plurality of layers n, but for simplicity a single layer is show in FIG. 8. The MAC units 810 each receive input or analog inputs IA, (IA₁, IA₂, . . . ) and each produce an output 820 (820a, 820b.). The MAC units 810 in FIG. 8, can be k bits in length (k inputs or k multipliers). The outputs 820 produced from all the MAC units 810 of a single layer can be accumulated together at 850. For example, the accumulation can be realized by simply connecting the outputs 820 of MAC units 810 together, e.g., at a single node to realize a sum or accumulation of the outputs. That is, the accumulation operation is achieved by simply connecting all the C-2C ladder output nodes, allowing their electric charges to merge or accumulate thereby forming a natural analog summation. The voltage of this combined node will be determined by the total charge held by the overall capacitance.

The total output or output activation (OA) of a layer can be expressed as follows:

$${OA}^{n} = {\sum }_{j = 0}^{k - 1} {\sum }_{i = 0}^{m - 1} {IA}_{j}^{n} \times {W}_{j ( i )}^{n} \times 2 i$$

where for a layer there are k inputs, and m MAC units.

The output could be expressed also as follows, again where the nth MAC unit contains k multipliers, and the combined electric charge from its ladders produces the output activation (OA),

$${OA}^{n} = \frac{1}{k} \times {\sum }_{j = 0}^{k - 1} [ {IA}_{j ∈ ( 0 to k - 1 )}^{n} \times {\sum }_{i = 0}^{m - 1} {W}_{j , i}^{n} \times \frac{1}{{2}^{m - i}} ]$$

The scaling factor of 1/k is a result of the combined capacitance and ensures that the output signal does not exceed a supply voltage of the system (e.g., 1 volt), and thus eliminating all potential overflow conditions.

For analog processing circuitries described herein, there can be multiple layers of MAC units producing multiple outputs or output activations, e.g., for performing a Spatial Fourier transform.

By implementing spatial compression in analog baseband, hardware simplifications are realized such as reducing the number of ADCs or ADC clock rate, which in turn improve cost and power efficiency.

Analog computations are inherently low power and low latency. For the DFT implementation described above, the entire received signal vector is transformed to beam-space in a single clock cycle, incurring almost no buffering or processing delay. With a nominal supply voltage of 1V, the C-2C ladder-based in-memory computing architecture can run at a speed of 4 GHz, while achieving an energy consumption of 20.3 fJ (femto-joule) with 22 nm CMOS process. The corresponding energy efficiency is around 100 TOPS/W (tera operations per second per watt) with 8-bit precision. If we lower the supply voltage to 0.6 volt, the maximum speed is reduced to 1 GHz, but the energy efficiency can be improved by about 2.5×.

The radio communications system and analog processing circuitries solution can outperform existing (or under development) techniques by a large margin. In particular, its power efficiency can greater than 50 times than that of its digital counterparts, and it achieves higher number of bits with the same power consumption when competing with other top-tier charge based analog computing methods. The performance is close to that of photonic computing, while remaining fully compatible with conventional CMOS technology without relying on additional signal conversions.

In the following, various aspects of the present disclosure will be illustrated in the following examples:

Example 1 is a radio communication system including an antenna array comprising a plurality of antenna elements configured to receive a plurality of radio frequency (RF) signals; RF circuitry coupled to the antenna array configured to downconvert the RF signals to generate analog baseband signals; and analog processing circuitry coupled to the RF circuitry and configured to generate spatially compressed beamspace domain analog signals from the analog baseband signals.

Example 2 is the subject matter of Example 1, wherein the analog processing circuitry configured to generate the spatially compressed beamspace domain analog signals can include the analog processing circuitry configured to apply, in analog, a spatial Fourier transform to the analog baseband signals.

Example 3 is the subject matter of Example 2, wherein the analog processing circuitry may include a plurality of multiply-accumulate (MAC) circuits configured to generate the spatially compressed beamspace domain analog signals.

Example 4 is the subject matter of Example 3, wherein each of the plurality of MAC circuits may include a capacitor ladder structure.

Example 5 is the subject matter of Example 4, wherein the capacitor ladder structure may include: a plurality of branches, each branch including a first capacitor and a switch configured to electrically couple the first capacitor to a reference potential, a plurality second capacitors arranged in series so that each of the second capacitors is located between adjacent branches of the plurality of branches and wherein the plurality of second capacitors is coupled at one end to an output of the respective MAC circuit.

Example 6 is the subject matter of Example 5, wherein each of the first capacitors may have a capacitance equal to a first capacitance value, and wherein each of the plurality of second capacitors may have a capacitance equal to twice the first capacitance value.

Example 7 is the subject matter of Example 5 or 6, wherein the switches may be controlled by digital bits being binary representation of multiplication weights, and wherein the input to the respective MAC circuit is the reference potential.

Example 8 is the subject matter of Example 7, which may further include a memory circuit configured to store and provide the digital bits to the switches of the plurality of MAC circuits.

Example 9 is the subject matter of Example 8, wherein the memory circuit may be implemented as a plurality of Static Random-Access Memory (SRAM) cells, wherein the digital bits are stored in and provided by the plurality of SRAM cells.

Example 10 is the subject matter of Example 8 or 9, wherein the plurality of MAC circuits may be implemented in Complementary Metal-Oxide-Semiconductor (CMOS) technology.

Example 11 is the subject matter of Example 10, wherein each of the switches of the plurality of MAC circuits may be implemented as a pair of gates receiving the digital bits from the memory circuit.

Example 12 is the subject matter of Example 10 or 11, wherein each of the first capacitors and each of the second capacitors of the plurality of MAC units may be implemented as metal-oxide-metal capacitors.

Example 13 is the subject matter of Example 10, wherein the SRAM cells of the memory circuit may be implemented together with the plurality of MAC circuits in CMOS technology.

Example 14 is the subject matter of Example 13, wherein the SRAM cells and the plurality of MAC circuits implemented together in CMOS technology may include a plurality of arithmetic memory cells, with each cell including a SRAM cell adjacent to a MAC circuit so that the SRAM provides the adjacent MAC circuit the digital bits for the switch of the MAC circuit.

Example 15 is the subject matter of any of Examples 1 to 11, which m ay further include: one or more analog-to-digital converters (ADCs) configured to digitize the spatially compressed beamspace domain analog signals.

Example 16 is the subject matter of any of Examples 1 to 15, wherein the antenna array may include a two-dimensional array of antenna elements.

Example 17 is the subject matter of any of Examples 1 to 16, wherein the antenna array may be a multiple-input multiple-output (MIMO) antenna array.

Example 18 is the subject matter of any of Examples 1 to 17, wherein the RF circuitry may include a plurality of RF chains.

Example 19 is the subject matter of Example 18, wherein the plurality of RF chains can correspond respectively to the plurality of antenna elements of the antenna array so that each RF chain is configured to downconvert signals from the corresponding antenna element.

Example 1A is a method for a radio communication system, the method including: receiving, at antenna array, a plurality of radio frequency (RF) signals; generating analog baseband signals by downconverting the RF signals; and generating spatially compressed beamspace domain analog signals from the analog baseband signals.

Example 2A is the subject matter of Example 1A, wherein the spatially compressed beamspace domain analog signals can include applying, in analog, a spatial Fourier transform to the analog baseband signals.

Example 3A is the subject matter of Example 1A or 2A, wherein generating the spatially compressed signals can include generating spatially compressed signal using the analog processing circuitry comprising a plurality of multiply-accumulate (MAC) circuits configured to generate the spatially compressed beamspace domain analog signals.

Example 4A is the subject matter of Example 3A, wherein each of the plurality of MAC circuits can include a capacitor ladder structure.

Example 5A is the subject matter of Example 4A, wherein the capacitor ladder structure can include: a plurality of branches, each branch including a first capacitor and a switch configured to electrically couple the first capacitor to a reference potential, a plurality second capacitors arranged in series so that each of the second capacitors is located between adjacent branches of the plurality of branches and wherein the plurality of second capacitors is coupled at one end to an output of the respective MAC circuit.

Example 6A is the subject matter of Example 5, wherein each of the first capacitors can have a capacitance equal to a first capacitance value, and wherein each of the plurality of second capacitors can have a capacitance equal to twice the first capacitance value.

Example 7A is the subject matter of Example 5A or 6A, wherein the switches can be controlled by digital bits being binary representation of multiplication weights, and wherein the input to the respective MAC circuit is the reference potential.

Example 8A is the subject matter of Example 7A, which may further a memory circuit configured to store and provide the digital bits to the switches of the plurality of MAC circuits.

Example 9A is the subject matter of Example 8A, wherein the memory circuit can be implemented as a plurality of Static Random-Access Memory (SRAM) cells, wherein the digital bits are stored in and provided by the plurality of SRAM cells.

Example 10A is the subject matter of Example 8A or 9A, wherein the plurality of MAC circuits can be implemented in Complementary Metal-Oxide-Semiconductor (CMOS) technology.

Example 11A is the subject matter of Example 10A, wherein each of the switches of the plurality of MAC circuits can be implemented as a pair of gates receiving the digital bits from the memory circuit.

Example 12A is the subject matter of Example 10A or 11A, wherein each of the first capacitors and each of the second capacitors of the plurality of MAC units can be implemented as metal-oxide-metal capacitors.

Example 13A is the subject matter of Example 10A, wherein the SRAM cells of the memory circuit can be implemented together with the plurality of MAC circuits in CMOS technology.

Example 14A is the subject matter of Example 13A, wherein the SRAM cells and the plurality of MAC circuits implemented together in CMOS technology can includer a plurality of arithmetic memory cells, with each cell including a SRAM cell adjacent to a MAC circuit so that the SRAM provides the adjacent MAC circuit the digital bits for the switch of the MAC circuit.

Example 15 is the subject matter of any of Examples 1A to 11A, which may further include: digitizing, using a plurality analog-to-digital converter (ADC), the spatially compressed beamspace domain analog signals.

Example 16 is the subject matter of any of Examples 1A to 15A, wherein the antenna array can include a two-dimensional array of antenna elements.

Example 17 is the subject matter of any of Examples 1A to 16A, wherein the antenna array can be a multiple-input multiple-output (MIMO) antenna array.

While the above descriptions and connected figures may depict electronic device components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

1. A system comprising:
an antenna array comprising a plurality of antenna elements configured to receive a plurality of radio frequency (RF) signals;
RF circuitry coupled to the antenna array configured to downconvert the RF signals to generate analog baseband signals; and
analog processing circuitry coupled to the RF circuitry and configured to generate spatially compressed beamspace domain analog signals from the analog baseband signals.

2. The system of claim 1,
wherein the analog processing circuitry configured to generate the spatially compressed beamspace domain analog signals comprises the analog processing circuitry configured to apply, in analog, a spatial Fourier transform to the analog baseband signals.

3. The system of claim 2,
wherein the analog processing circuitry comprises a plurality of multiply-accumulate (MAC) circuits configured to generate the spatially compressed beamspace domain analog signals.

4. The system of claim 3,
wherein each of the plurality of MAC circuits comprises a capacitor ladder structure.

5. The system of claim 4,
wherein the capacitor ladder structure comprises:
a plurality of branches, each branch comprises a first capacitor and a switch configured to electrically couple the first capacitor to a reference potential,
a plurality second capacitors arranged in series so that each of the second capacitors is located between adjacent branches of the plurality of branches and wherein the plurality of second capacitors is coupled at one end to an output of the respective MAC circuit.

6. The system of claim 5,
wherein each of the first capacitors has a capacitance equal to a first capacitance value, and
wherein each of the plurality of second capacitors have a capacitance equal to twice the first capacitance value.

7. The system of claim 5,
wherein the switches are controlled by digital bits being binary representation of multiplication weights, and
wherein the input to the respective MAC circuit is the reference potential.

8. The system of claim 7, further comprising
a memory circuit configured to store and provide the digital bits to the switches of the plurality of MAC circuits.

9. The system of claim 8,
wherein the memory circuit is implemented as a plurality of Static Random-Access Memory (SRAM) cells, wherein the digital bits are stored in and provided by the plurality of SRAM cells.

10. The system of claim 8,
wherein the plurality of MAC circuits is implemented in Complementary Metal-Oxide-Semiconductor (CMOS) technology.

11. The system of claim 10,
wherein each of the switches of the plurality of MAC circuits is implemented as a pair of gates receiving the digital bits from the memory circuit.

12. The system of claim 10,
wherein each of the first capacitors and each of the second capacitors of the plurality of MAC units is implemented as metal-oxide-metal capacitors.

13. The system of claim 10,
wherein the SRAM cells of the memory circuit are implemented together with the plurality of MAC circuits in CMOS technology.

14. The system of claim 13,
wherein the SRAM cells and the plurality of MAC circuits implemented together in CMOS technology comprise a plurality of arithmetic memory cells, each cell including a SRAM cell adjacent to a MAC circuit so that the SRAM provides the adjacent MAC circuit the digital bits for the switch of the MAC circuit.

15. The system of claim 1, further comprising:
a plurality of analog-to-digital converters (ADCs) configured to digitize the spatially compressed beamspace domain analog signals.

16. The system of claim 1,
wherein the antenna array comprises a two-dimensional array of antenna elements.

17. The system of claim 1,
wherein the antenna array is a multiple-input multiple-output (MIMO) antenna array.

18. The system of claim 1,
wherein the RF circuitry comprises a plurality of RF chains, and wherein the plurality of RF chains corresponds, respectively to the plurality of antenna elements of the antenna array so that each RF chain is configured to downconvert signals from the corresponding antenna element.

19. A method for a radio communication system, the method comprising:
receiving, at antenna array, a plurality of radio frequency (RF) signals;
generating analog baseband signals by downconverting the RF signals; and
generating spatially compressed beamspace domain analog signals from the analog baseband signals.

20. The method of claim 19,
wherein the spatially compressed beamspace domain analog signals comprises applying, in analog, a spatial Fourier transform to the analog baseband signals.
